(19) United States
(12) Patent Application Publication
(10) Pub. No.: US 2014/0266286 A1
(43) Pub. Date: Sep. 18, 2014

(54) THROUGH-SUBSTRATE VIA WITH A FUSE STRUCTURE

(71) Applicant: QUALCOMM INCORPORATED, (US)

(72) Inventors: Vidhya Ramachandran, San Diego, CA (US); Shiqun Gu, San Diego, CA (US); Brian M. Henderson, Escondido, CA (US); Michael Scott DiBattista, San Diego, CA (US); Babak Motamedi, San Diego, CA (US); George F. Gaut, San Diego, CA (US)

(73) Assignee: QUALCOMM INCORPORATED, San Diego, CA (US)

(21) Appl. No.: 13/801,009

(22) Filed: Mar. 13, 2013

(51) Int. Cl. H01L 23/522; H01L 23/525; G01R 31/26; G06F 17/50

(52) U.S. Cl. CPC H01L 23/5226; G06F 17/5068; H01L 23/5256; G01R 31/2601
USPC 324/759.01; 257/529; 716/110

(57) ABSTRACT

A device includes a conductive via to provide an electrical path through a substrate. The device further includes a conductive element. The device further includes a fuse coupled to the conductive via and coupled to the conductive element to provide a conductive path between the conductive via and the conductive element. The conductive path enables testing of continuity of at least a portion of the conductive via. The fuse is configured to be disabled after the testing of the continuity of the conductive via.

### I. FIELD

The present disclosure is generally related to through-substrate via in semiconductor devices.

### II. BACKGROUND

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

A modern electrical system or device (e.g., a wireless telephone) may include a variety of electrical devices. The electrical devices may be arranged on different chips according to design, performance, and/or processing criteria. The chips may be stacked, bonded, and packaged in such a way that the electrical devices located on the chips are electrically connected and function together as a system.

To electrically connect the devices on the different chips, through-substrate via (TSV) technology may be used. TSVs may be formed in a silicon, or other substrate such as glass, chip with other integrated circuit (IC) devices using semiconductor processes (e.g., lithography, etching, deposition, and surface polish and planarization). The chips are then stacked and electrically connected through the TSVs. TSVs may also be formed on chips with no active devices, such as passive interposer chips, or passive interposer die.

To verify that the TSVs are properly fabricated, a continuity test may be performed. Typically, a single side of the chip is accessible for testing while the other side is used to support the chip. As a result, continuity testing may be postponed until stacking and bonding has been performed.

### III. SUMMARY

This disclosure presents particular embodiments of TSVs with a fuse structure. When only a single side of a chip is accessible for testing while the other side is used to support the chip, directly testing continuity from one side of the chip to the other is difficult before stacking and bonding is performed. Use of the fuse structure may solve difficulties of performing a continuity test to detect defects of the TSVs.

In a particular embodiment, a device includes a conductive via to provide an electrical path through a substrate. The device further includes a conductive element. The device further includes a fuse coupled to the conductive via and coupled to the conductive element to provide a conductive path between the conductive via and the conductive element. The conductive path enables testing of the continuity of the conductive via. The fuse is configured to be disabled after the testing of the continuity of the conductive via.

In another particular embodiment, a device includes means for establishing a first electrical path through a substrate. The device further includes means for establishing a second electrical path. The device further includes means for establishing a permanently severable conductive path between the first electrical path and the second electrical path. The permanently severable conductive path enables testing of the continuity of the first electrical path through the substrate. The permanently severable conductive path may be severed after the testing of the continuity of the first electrical path.

In another particular embodiment, a method includes testing continuity of at least a portion of a conductive via and a conductive element through a fuse that provides a conductive path between the conductive via and the conductive element. The method further includes disabling the fuse after testing the continuity.

In another particular embodiment, a non-transitory computer-readable medium includes instructions that, when executed by a processor, cause the processor to perform operations including initiating testing continuity of at least a portion of a conductive via and a conductive element through a fuse. The fuse provides a conductive path between the conductive via and the conductive element. The operations further include initiating disabling the fuse after testing the continuity.

In another particular embodiment, a method includes receiving a data file including design information corresponding to a semiconductor device. The method further includes fabricating the semiconductor device according to the design information. The semiconductor device includes a conductive via to provide an electrical path through a substrate, a conductive element, and a fuse coupled to the conductive via and coupled to the conductive element to provide a conductive path between the conductive via and the conductive element.

One particular advantage provided by at least one of the disclosed embodiments is that, when no appropriate device is available to electrically connect with the TSVs to constitute a continuous conductive path, a continuity test can still be applied to detect defects of the TSVs through a fuse which is formed during fabrication of the TSVs and which may be disabled after the continuity test. For example, when only one side of a TSV is accessible for continuity testing, a conductive path may be formed through the TSV, a fuse, and a second conductive element that is accessible for testing, where the fuse may later be deactivated.

Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a cross-sectional diagram of a particular embodiment of a semiconductor device including through-silicon vias (TSVs) with a fuse structure;

FIG. 2 is a diagram of an illustrative embodiment of a device that includes multiple conductive vias coupled to a conductive element through a fuse structure;

FIG. 3 is a flowchart of an illustrative of an illustrative embodiment of a method of continuity testing of a semiconductor device;

FIG. 4 is a block diagram of a particular embodiment of a wireless communication device that includes TSVs with fuse structure; and

FIG. 5 is a flow chart of a particular embodiment illustrating processes of manufacturing an electronic device that includes TSVs with a fuse structure.

### V. DETAILED DESCRIPTION

The present disclosure describes particular embodiments in specific contexts, such as designs of through-substrate vias (TSVs) with a fuse structure and methods of making and testing the TSV with the fuse structure. However, features, methods, structures or characteristics described according to the particular embodiments may also be combined in other suitable manners to form one or more other embodiments. In addition, the drawings illustrate relative relationships between the features, methods, structures, or characteristics, and thus may not be drawn in scale.

Referring to FIG. 1, a cross-sectional diagram of a particular embodiment of a semiconductor device 100 including a TSV with a fuse structure is shown. The semiconductor device 100 may include conductive vias 110, 112. The conductive vias 110, 112 may provide respective electrical paths through a substrate 105. For example, the conductive vias 110, 112 may provide an electrical path through the substrate 105 such that one end of the electrical path is accessible from a bottom side 108 of the substrate 105 and another end of the electrical path is accessible from a top side 106 of the substrate 105. For example, the conductive via 110 is shown as providing an electrical path through the substrate 105 in that the conductive via 110 completely traverses the substrate enabling access to the conductive via 110 from either side 106, 108 of the substrate 105. The substrate 105 may be composed of any material suitable for the specific design and functional requirements of the semiconductor device 100. In one particular embodiment, the substrate 105 is a silicon wafer, and the conductive vias 110, 112 are TSVs. In another particular embodiment, the substrate 105 is a glass wafer, and the conductive vias 110, 112 are through glass vias (TGVs). The conductive vias 110, 112 may also provide respective electrical paths within a device layer 104. Alternatively, multiple via sub-portions may be coupled together within the device layer 104 and/or the substrate 105 to form the conductive vias 110, 112. The conductive vias 110, 112 may be used to electrically connect devices on one chip with devices on another chip of a package.

The semiconductor device 100 may include conductive elements 111, 113. In a particular embodiment the conductive elements 111, 113 are conductive vias. For example, the conductive elements 111, 113 may be TSVs or TGVs. Thus, as illustrated by FIG. 1, each of the conductive vias 110, 112 and each of the conductive elements 111, 113 may each be a TSV. In another particular embodiment, the conductive elements 111, 113 are ground lines and may be accessible through another conductive contact or via, such as a ground contact. In another particular embodiment, the conductive elements 111, 113 are active or passive device within the device layer 104. The conductive vias 110, 112, the conductive elements 111, 113, or any combination thereof, may be coupled to bump connects 130-133 to facilitate assembly of the semiconductor device 100 into a packaged device. For example, the semiconductor device 100 may be a passive interposer wafer or die. In another example, the semiconductor device 100 may be an active wafer or die.

Each of the conductive vias 110, 112 may be paired with one of the conductive elements 111, 113. Each via-element pair 110, 111 and 112, 113 may be coupled through a fuse 120, 121 that, when intact, provides a conductive path between the conductive vias 110, 112 and the conductive elements 111, 113. For example, referring to FIG. 1, the fuse 120 may provide a conductive path between the conductive via 110 and the conductive element 111. When intact, the fuse 121 may provide a first conductive path between the conductive via 112 and the conductive element 113. A fuse may be any structure or material that is conductive until the fuse is “blown” (e.g., disabled, severed, broken down, or at least partially destroyed). After a fuse is blown, the fuse is substantially or entirely non-conductive. In the example illustrated in FIG. 1, the fuse 121 is shown as blown. Examples of fuses include laser fuses, e-fuses, thin metal or conductive lines that are designed to break in response to a current exceeding a threshold amount, or any other type of passive device that can be transitioned from a conductive state to a non-conductive state. To illustrate, fuses may be formed of copper, aluminum, silicide, silicide/polysilicon, one or more other materials, or any combination thereof.

The conductive via 110, the fuse 120, and the conductive element 111 may form a second conductive path 140 and a third conductive path 141. The second conductive path 140 may include a first end and a second end, where both the first end and the second end are accessible from one side of the semiconductor device 100. For example, the ends of the second conductive path 140 may be accessible from a bottom side 108 of the semiconductor device 100. As an additional example, ends of the third electrical path 141 may be accessible from a top side 106 of the semiconductor device 100.

Alternatively, one end of the second conductive path 140 may be accessible from the bottom side 108 and the other end of the second conductive path 140 may be attached to a reference voltage source (not shown), a reference current source (not shown), or a reference heat source (now shown). Similarly, one end of the third conductive path 141 may be accessible from the top side 106 and the other end of the third conductive path 141 may be attached to the reference voltage source, the reference current source, or the reference heat source.

In operation, the second conductive path 140 and the third conductive path 141 may enable testing of connectivity of the conductive via 110. For example, the testing may include applying a voltage, an electrical current, or heat to one end of the second conductive path 140. The voltage, the electrical current, or the heat may be applied by coupling a voltage source, an electrical current source, or a heat source to the conductive vias 110, 112 or to the conductive elements 111, 113. The testing may further include sensing the voltage, the electrical current, or the heat at the other end of the second conductive path 140. Because the fuse 120 forms a conductive path between the conductive via 110 and the conductive element 111, the fuse 120 enables sensing a voltage, an electrical current, or heat applied to one end of the second conductive path 140 from the other end of the second conductive path 140. Similarly, the fuse 120 enables sensing a voltage, an electrical current, or heat applied to one end of the third conductive path 141 from the other end of the third conductive path 141.

When the conductive vias 110, 112 are formed, a fabrication process may cause defects (e.g., openings or voids) in the conductive vias 110, 112. For example, the conductive via 112 is shown in FIG. 1 to have three voids 150-152. Testing the continuity or connectivity of the conductive via 112 from the bottom side 108 of the semiconductor device 100 may discover the presence of at least one of the voids 151, 152. Testing the continuity or connectivity of the conductive via 112 from the top side 106 of the semiconductor device 100 may discover the void 150.

After the continuity tests are performed, the fuses 120, 121 can be disabled (e.g., blown), such as by use of a laser beam 160 or an electrical current. For example, the fuse 121 may be irradiated by the laser beam 160 and may become non-conductive (e.g., due to mechanical failure or ablation of a portion of the fuse 121) as a result of the irradiation. As another example, a large electrical current may be passed through the fuse 121, which may cause the fuse 121 to become non-conductive, such as due to failure of a portion of the fuse 121 due to resistive heating of the portion in response to the electrical current. Disabling the fuses 120, 121 prevents or at least inhibits conduction through the fuses 120, 121 during the operation of the semiconductor device.

In the case that only one side of the device 100 may be accessed (e.g., the other side of the device may be coupled to a support mechanism during a manufacturing process) testing continuity of the electrical paths through the substrate 105 may be difficult. Further, when the semiconductor device 100 is an interposer die, continuity testing before assembling the semiconductor device 100 with one or more other devices (e.g., devices that are intended to be used during normal device operation) may identify problems early in a manufacturing process. However, when there are no operational devices on the substrate 105 or on the device layer 104 continuity testing may be difficult. The fuses 120, 121 may facilitate continuity testing of the conductive vias 110, 112 when only one side of the semiconductor device 100 is accessible at a time, when no operational devices are coupled to the semiconductor device 100, or both. The fuses 120, 121, when intact, may connect the conductive vias 110, 112 respectively to the conductive elements 111, 113. When only the bottom side 108 of the semiconductor device 100 is accessible for testing, the fuses 120, 121, when intact, can be used to provide a conductive path (e.g., the second conductive path 140) to test continuity of lower portions of the conductive vias 110, 112. When the semiconductor device 100 is inverted and only the top side 106 of the semiconductor device 100 is accessible for testing, the fuses 120, 121, when intact, may be used to provide a conductive path (e.g., the third conductive path 141) to test continuity of upper portions of the conductive vias 110, 112. Thus, end-to-end continuity of the conductive vias 110, 112 may be tested in a stepwise manner as the top side 106 and the bottom side 108 become available at different times during the manufacturing process.

While the embodiment shown in FIG. 1 illustrates two (2) conductive vias 110, 112, and two (2) conductive elements 111, 113, other embodiments may include more than two (2) or fewer than two (2) conductive vias and more than two (2) or fewer than two (2) conductive elements. Additionally, as shown in FIG. 1, each conductive via 110, 112 may be a TSV and each conductive element 111, 113 may also be a TSV. In other embodiments, the conductive elements 111, 113 may be ground lines, active devices, passive device, other elements that may be found on a semiconductor device, or a combination thereof. Although each conductive via 110, 112 is depicted as being coupled to respective fuses 120, 121, with the fuses 120, 121 being coupled to respective conductive elements 111, 113, in other embodiments a TSV continuity testing fuse structure may have a different arrangement. For example, an alternative TSV continuity testing fuse structure may include a plurality of conductive vias to provide respective electrical paths through a substrate, a conductive element, and a plurality of fuses coupled respectively to the plurality of conductive vias and coupled to the conductive element. The conductive element may be another conductive via through the substrate, or the conductive element may be another type of conductive element, such as a metal wire in the device layer (e.g., a power supply line or a ground line, as non-limiting examples), as illustrated in FIG. 2.

Referring to FIG. 2, an embodiment of a device 200 that has a first conductive via 202, a second conductive via 212, and a third conductive via 222 is shown. For example, the first conductive via 202, the second conductive via 212, and the third conductive via 222 may be TSVs. The conductive vias 202, 212, 222 are coupled to a conductive element 230 through a first fuse 204, a second fuse 214, and a third fuse 224, respectively. The conductive element 230 may be a ground line, as an illustrative example, and may be accessible through another conductive contact or via, such as a ground contact 232. By having multiple TSVs coupled to a single conductive line or element through fuses, TSV continuity testing may be performed to detect discontinuities corresponding to individual TSVs and/or to pairs of TSVs.

To illustrate, continuity testing may be performed from the ground contact 232 to the first conductive via 202, from the ground contact 232 to the second conductive via 212, and from the ground contact 232 to the third conductive via 222. Alternatively, continuity testing may be performed between two or more of the conductive vias 202, 212, 222, such as to test continuity of a conductive path that extends from a first test probe in contact with the first conductive via 202, through the first fuse 204, through the conductive element 230, through the third fuse 224, and through the third conductive via 222 to a second test probe. Continuity may be tested by applying an electrical current, a voltage, or heat at one test probe and monitoring a resulting condition (e.g., current, voltage, or temperature change) at another test probe. The fuses 204, 214, and 224 may be disabled after the testing and prior to normal device operation.

Testing the continuity of the vias 202, 212, 222 as described above may be accomplished from a top side of the device 200. Alternatively or in addition, testing the continuity of the vias 202, 212, 222 may be accomplished from a bottom side of the device 200. Alternatively, end-to-end continuity of the conductive vias 202, 212, 222 may be tested in a stepwise manner as the top side and the bottom side of the device 200 become available at different times during the manufacturing process.

Referring to FIG. 3, a flowchart of an embodiment of a method 300 of testing continuity is depicted. In an illustrative embodiment, the method 300 may be performed to test the device 100 of FIG. 1 or the device 200 of FIG. 2 (e.g., using a test device). The method 300 includes, at 302, testing continuity of at least a portion of a conductive via and a conductive element through a fuse that provides a conductive path between the conductive via and the conductive element. For example, referring to FIG. 1, continuity of a first portion (e.g., a portion forming part of the conductive path 141) of the conductive via 110 may be tested through the fuse 120 and the conductive element 111. Testing continuity may be performed from the top side 106 of the semiconductor device 100, in which case the first portion is the upper portion of the conductive via 110. Testing continuity may also be performed from the bottom side 108 of the semiconductor device 100, in which case the first portion is the lower portion of the conductive via 110. As another example, continuity of a portion of the conductive via 112 may be tested through the fuse 121 and the conductive element 113, when the fuse 121 is intact.

Testing continuity of the portion of the conductive via may include, at 304, coupling an electric current source, a voltage source, or a heat source to the conductive via or the conductive element. For example, the electric current source, the voltage source, or the heat source may be coupled to the conductive vias 110, 112 of FIG. 1. Testing continuity of the portion of the conductive via may further include, at 306, applying an electric current, a voltage, or heat to the conductive via or to the conductive element. Testing continuity of the portion of the conductive via may further include, at 308, sensing the electric current, the voltage, or the heat at the conductive via or the conductive element to which the electric current, the voltage, or the heat was not applied. For example, referring to FIG. 1, an electric current, a voltage, or heat may be applied to the conductive via 110. Due to the conductive paths 140, 141, the electric current, the voltage, or the heat may be sensed at the conductive element 111. Alternatively, the electric current, the voltage, or the heat may be applied to the conductive element 111 and sensed at the conductive via 110. In an illustrative embodiment, the electric current, the voltage, or the heat may be applied at the same side of a semiconductor device 100 at which it is sensed. For example, the voltage, the electric current, or the heat may be applied to the conductive via 110 at the bottom side 108 of the semiconductor device 100 and sensed at the conductive element 111 at the bottom side 108 of the semiconductor device 100. Alternatively, the voltage, the electric current, or the heat may be applied to the conductive via 110 at the top side 106 of the semiconductor device 100 and sensed at the conductive element 111 at the top side 106 of the semiconductor device 100.

The method 300 may include, at 310, disabling the fuse after testing the continuity. For example, referring to FIG. 1, the fuse 121 has been disabled by the laser beam 160. In this example, the fuse 121 may be irradiated by the laser 160 and may become non-conductive (e.g., due to mechanical/thermal failure) as a result of the irradiation. As another example, an electrical current applied to the fuse may cause the fuse to become non-conductive (e.g., due to mechanical/thermal failure of the fuse 121 due to resistive heating caused by the electrical current). Disabling the fuse may prevent, or significantly decrease, conduction through the fuses. In some cases, a disabled fuse may continue to be somewhat conductive such that a small leakage current may occur during normal device operation.

The method 300 of FIG. 3 may be implemented using a field-programmable gate array (FPGA) device, an application-specific integrated circuit (ASIC), a processing unit such as a central processing unit (CPU), a digital signal processor (DSP), a controller, another hardware device, firmware device, or any combination thereof. As an example, the method 300 of FIG. 3 can be performed by a processor, integrated into an electronic device, where the processor executes instructions, as described with respect to FIG. 5.

Referring to FIG. 4, a block diagram of a particular illustrative embodiment of a wireless communication device is depicted and generally designated 400. The device 400 includes a processor 410, such as a digital signal processor (DSP), coupled to a memory 432. FIG. 4 also shows a display controller 426 that is coupled to the processor 410 and to a display 428. A coder/decoder (CODEC) 434 can also be coupled to the processor 410. A speaker 436 and a microphone 438 can be coupled to the CODEC 434.

FIG. 4 shows a TSV continuity testing fuse structure 464 (e.g., the conductive vias 110, 112, the conductive elements 111, 113, and the fuses 120, 121 of FIG. 1 or the conductive vias 202, 212, 222, the conductive element 230, and the fuses 204, 214, 224 of FIG. 2). Although the TSV continuity testing fuse structure 464 is shown as a separate device, the TSV continuity testing fuse structure 464 can be incorporated in circuits of one or more of the devices or components of the wireless communication device 400 (e.g., the processor 410, the memory 432, the display controller 426, the display 428, the CODEC 434, the speaker 436, and the microphone 438) shown in FIG. 4. For example, circuits of one or more of the devices may include the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1 and the fuses 204, 214, 224 of FIG. 2, or any combination thereof. The TSV continuity testing fuse structure 464 may also, or in the alternative, be used in other devices and may be also applied in other configurations.

FIG. 4 also indicates that a wireless controller 440 can be coupled to the processor 410 and to a wireless antenna 442. In a particular embodiment, the processor 410, the display controller 426, the memory 432, the CODEC 434, and the wireless controller 440 are included in a system-in-package or system-on-chip device 422. In a particular embodiment, an input device 430 and a power supply 444 are coupled to the system-on-chip device 422. Moreover, in a particular embodiment, as illustrated in FIG. 4, the display 428, the input device 430, the speaker 436, the microphone 438, the wireless antenna 442, and the power supply 444 are external to the system-on-chip device 422. However, each of the display 428, the input device 430, the speaker 436, the microphone 438, the wireless antenna 442, and the power supply 444 can be coupled to a component of the system-on-chip device 422, such as an interface or a controller.

The foregoing disclosed devices and functionalities may be designed and configured into computer files (e.g. RTL, GDSII, GERBER, etc.) stored on computer-readable media. Some or all such files may be provided to fabrication handlers who fabricate devices based on such files. Resulting products include semiconductor wafers that are then cut into semiconductor die and packaged into a semiconductor chip. The chips are then employed in devices described above.

FIG. 5 is a flow chart of a particular embodiment illustrating processes of manufacturing an electronic device manufacturing process 500. Physical device information 502 is received at the manufacturing process 500, such as at a research computer 506. The physical device information 502 may include design information representing at least one physical property of a semiconductor device. For example, the physical device information 502 may include physical parameters, material characteristics, and structure information that is entered via a user interface 504 coupled to the research computer 506. The research computer 506 includes a processor 508, such as one or more processing cores, coupled to a computer-readable medium such as a memory 510. The memory 510 may store computer-readable instructions that are executable to cause the processor 508 to transform the physical device information 502 to comply with a file format and to generate a library file 512.

In a particular embodiment, the library file 512 includes at least one data file including the transformed design information. For example, the library file 512 may include a library of semiconductor devices including a device that includes a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof), that is provided for use with an electronic design automation (EDA) tool 520.

The library file 512 may be used in conjunction with the EDA tool 520 at a design computer 514 including a processor 516, such as one or more processing cores, coupled to a memory 518. The EDA tool 520 may be stored as processor executable instructions at the memory 518 to enable a user of the design computer 514 to design a circuit including a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof), of the library file 512. For example, a user of the design computer 514 may enter circuit design information 522 via a user interface 524 coupled to the design computer 514. The circuit design information 522 may include design information representing at least one physical property of a semiconductor device, such as a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof). To illustrate, the circuit design property may include identification of particular circuits and relationships to other elements in a circuit design, positioning information, feature size information, interconnection information, or other information representing a physical property of a semiconductor device.

The design computer 514 may be configured to transform the design information, including the circuit design information 522, to comply with a file format. To illustrate, the file formation may include a database binary file format representing planar geometric shapes, text labels, and other information about a circuit layout in a hierarchical format, such as a Graphic Data System (GDSII) file format. The design computer 514 may be configured to generate a data file including the transformed design information, such as a GDSII file 526 that includes information describing a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof), in addition to other circuits or information. To illustrate, the data file may include information corresponding to a system-on-chip (SOC) that includes a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof), and that also includes additional electronic circuits and components within the SOC.

The GDSII file 526 may be received at a fabrication process 528 to manufacture a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof), according to transformed information in the GDSII file 526. For example, a device manufacture process may include providing the GDSII file 526 to a mask manufacturer 530 to create one or more masks, such as masks to be used with photolithography processing, illustrated as a representative mask 532. The mask 532 may be used during the fabrication process to generate one or more wafers 534, which may be tested and separated into dies, such as a representative die 536. The die 536 includes a circuit including a device that includes a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof).

The wafers 534 may be tested by a testing computer 570. The testing computer 570 includes a processor 571 and a memory 572. The memory 572 may include instructions, executable by the processor 571, to initiate performance of the operations of the method 300 of FIG. 3. Additionally, the die 536 may be tested by the testing computer 570. For example, the memory 572 may include instructions to initiate testing of continuity of at least a portion of a conductive path between a conductive via and a conductive element through a fuse that provides a conductive path between the conductive via and the conductive element. The memory 572 may further include instructions to initiate application of an electric current, a voltage, or heat to one of conductive via or to the conductive element. Additionally, the memory 572 may further include instructions to sense the electric current, the voltage, or the heat at the other of the conductive via or the conductive element. The memory 572 may also include instructions to initiate disabling (e.g., blowing) the fuse after testing the continuity.

The die 536 may be provided to a packaging process 538 where the die 536 is incorporated into a representative package 540. For example, the package 540 may include the single die 536 or multiple dies, such as a system-in-package (SiP) arrangement. The package 540 may be configured to conform to one or more standards or specifications, such as Joint Electron Device Engineering Council (JEDEC) standards.

Information regarding the package 540 may be distributed to various product designers, such as via a component library stored at a computer 546. The computer 546 may include a processor 548, such as one or more processing cores, coupled to a memory 550. A printed circuit board (PCB) tool may be stored as processor executable instructions at the memory 550 to process PCB design information 542 received from a user of the computer 546 via a user interface 544. The PCB design information 542 may include physical positioning information of a packaged semiconductor device on a circuit board, the packaged semiconductor device corresponding to the package 540 including a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof).

The computer 546 may be configured to transform the PCB design information 542 to generate a data file, such as a GERBER file 552 with data that includes physical positioning information of a packaged semiconductor device on a circuit board, as well as layout of electrical connections such as traces and vias, where the packaged semiconductor device corresponds to the package 540 including a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof). In other embodiments, the data file generated by the transformed PCB design information may have a format other than a GERBER format.

The GERBER file 552 may be received at a board assembly process 554 and used to create PCBs, such as a representative PCB 556, manufactured in accordance with the design information stored within the GERBER file 552. For example, the GERBER file 552 may be uploaded to one or more machines to perform various steps of a PCB production process. The PCB 556 may be populated with electronic components including the package 540 to form a representative printed circuit assembly (PCA) 558.

The PCA 558 may be received at a product manufacture process 560 and integrated into one or more electronic devices, such as a first representative electronic device 562 and a second representative electronic device 564. As an illustrative, non-limiting example, the first representative electronic device 562, the second representative electronic device 564, or both, may be selected from the group of a set-top box, a music player, a video player, an entertainment unit, a navigation device, a communications device, a personal digital assistant (PDA), a fixed location data unit, and a computer, into which a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof) are integrated. As another illustrative, non-limiting example, one or more of the electronic devices 562 and 564 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 5 illustrates remote units according to teachings of the disclosure, the disclosure is not limited to these illustrated units. Embodiments of the disclosure may be suitably employed in any device which includes active integrated circuitry including memory and on-chip circuitry.

A device that includes a TSV continuity testing fuse structure (e.g., the conductive vias 110, 112 of FIG. 1, the conductive vias 202, 212, 222 of FIG. 2, the conductive elements 111, 113 of FIG. 1, the conductive element 230 of FIG. 2, the fuses 120, 121 of FIG. 1, the fuses 204, 214, 224 of FIG. 2, or any combination thereof), may be fabricated, processed, and incorporated into an electronic device, as described in the illustrative process 500. One or more aspects of the embodiments disclosed with respect to FIGS. 1-3 may be included at various processing stages, such as within the library file 512, the GDSII file 526, and the GERBER file 552, as well as stored at the memory 510 of the research computer 506, the memory 518 of the design computer 514, the memory 550 of the computer 546, the memory of one or more other computers or processors (not shown) used at the various stages, such as at the board assembly process 554, and also incorporated into one or more other physical embodiments such as the mask 532, the die 536, the package 540, the PCA 558, other products such as prototype circuits or devices (not shown), or any combination thereof. Although various representative stages of production from a physical device design to a final product are depicted, in other embodiments fewer stages may be used or additional stages may be included. Similarly, the process 500 may be performed by a single entity or by one or more entities performing various stages of the process 500.

In conjunction with the described embodiments, an apparatus includes means for establishing a first electrical path through a substrate. For example, the means for establishing a first electrical path may include the conductive vias 110, 112 of FIG. 1, the conductive vias 202, 212, 222 of FIG. 2, another device configured establish an electrical path, or any combination thereof. The substrate may include the substrate 105 of FIG. 1.

The apparatus may also include means for establishing a second electrical path. For example, the means for establishing a first electrical path may include the conductive elements 111, 113 of FIG. 1, the conductive element 230 of FIG. 2, another device configured establish an electrical path, or any combination thereof.

The apparatus may further include means for establishing a permanently severable conductive path between the first electrical path and the second electrical path. For example, the means for establishing a permanently severable conductive path may include the fuses 120, 121 of FIG. 1, the fuses 204, 214, 224 of FIG. 2, another device configured to establish a permanently severable conductive path, or any combination thereof.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A device comprising:
a conductive via to provide an electrical path through a substrate;
a conductive element; and
a fuse coupled to the conductive via and coupled to the conductive element to provide a conductive path between the conductive via and the conductive element.

2. The device of claim 1, wherein the conductive via comprises a through-substrate via (TSV).

3. The device of claim 1, wherein the conductive element comprises a second conductive via through the substrate.

4. The device of claim 1, wherein the conductive via comprises a through-substrate via (TSV), and wherein the conductive element comprises a second TSV.

5. The device of claim 1, wherein the conductive via, the conductive element, and the fuse form at least a portion of a second conductive path, wherein a first end of the second conductive path and a second end of the second conductive path are accessible from one side of the substrate.

6. The device of claim 1, wherein the conductive via, the conductive element, and the fuse form at least a portion of a second conductive path, wherein a first end of the second conductive path is accessible from a side of the substrate and a second end of the second conductive path is coupled to a reference voltage source, a reference current source, or a reference heat source.

7. The device of claim 1, wherein the conductive path enables testing of continuity of at least a portion of the conductive via and at least a portion of the conductive element, and wherein the fuse is configured to be disabled after the testing.

8. The device of claim 1, wherein the fuse is configured to be disabled by a laser.

9. The device of claim 1, wherein the fuse is configured to be disabled by an electrical current.

10. The device of claim 1, wherein the fuse comprises copper, aluminum, silicide, silicide/polysilicon, or any combination thereof.

11. The device of claim 1, wherein the substrate comprises silicon.

12. The device of claim 1, wherein the substrate comprises glass.

13. The device of claim 1, integrated in at least one semiconductor die.

14. The device of claim 13, wherein the at least one semiconductor die is a passive interposer die.

15. The device of claim 1, further comprising a device selected from a set-top box, a music player, a video player, an entertainment unit, a navigation device, a communications device, a personal digital assistant (PDA), a fixed location data unit, and a computer, into which the conductive via, the conductive element, and the fuse are integrated.

16. A device comprising:
a means for establishing a first electrical path through a substrate;
a means for establishing a second electrical path; and
a means for establishing a permanently severable conductive path between the first electrical path and the second electrical path.

17. The device of claim 16, wherein the means for establishing a first electrical path, the means for establishing a second electrical path, and the means for establishing a permanently severable conductive path form at least a portion of a second conductive path, wherein a first end of the second conductive path and a second end of the second conductive path are accessible from one side of the substrate.

18. The device of claim 16, wherein the means for establishing a first electrical path, the means for establishing a second electrical path, and the means for establishing a permanently severable conductive path form at least a portion of a second conductive path, wherein a first end of the second conductive path is accessible from a side of a wafer or die and a second end of the second conductive path is coupled to a reference voltage source, a reference current source, or a reference heat source.

19. The device of claim 16, wherein the permanently severable conductive path is severable by a laser.

20. The device of claim 16, wherein the permanently severable conductive path is severable by an electrical current.

21. The device of claim 16, wherein the permanently severable conductive path enables testing of continuity of the first electrical path and the second electrical path.

22. The device of claim 16, integrated into a passive inter-pass wafer or die.

23. A method comprising:
testing continuity of at least a portion of a conductive via and a conductive element through a fuse that provides a conductive path between the conductive via and the conductive element; and
disabling the fuse after testing the continuity.

24. The method of claim 23, wherein the conductive via comprises a first through-silicon via (TSV).

25. The method of claim 24, wherein the conductive element comprises a second through-silicon via (TSV).

26. The method of claim 23, wherein testing the continuity includes coupling an electric current source, a voltage source, or a heat source to the conductive via or to the conductive element and applying an electric current, a voltage, or heat to the conductive via or the conductive element.

27. The method of claim 26, wherein testing the continuity further includes sensing the electric current, voltage, or heat at the conductive via or the conductive element to which the electric current source, the voltage source, or the heat source was not coupled.

28. The method of claim 27, wherein the coupling the electric current source, the voltage source, or the heat source to the conductive via or to the conductive element is performed on a same side of a wafer or a die as the sensing the electric current, the voltage, or the heat at the conductive via or the conductive element to which the electric current source, the voltage source, or heat source was not coupled.

29. The method of claim 23, wherein testing the continuity is initiated by a processor integrated into an electronic device.

30. A non-transitory computer-readable medium comprising instructions that, when executed by a processor, cause the processor to perform operations including:
initiating testing of continuity of at least a portion of a conductive via and a conductive element through a fuse that provides a conductive path between the conductive via and the conductive element; and
initiating disabling the fuse after testing the continuity.

31. The non-transitory computer-readable medium of claim 30, wherein testing the continuity includes coupling an electric current source, a voltage source, or a heat source to the conductive via or to the conductive element and applying an electric current, a voltage, or heat to the conductive via or the conductive element.

32. The non-transitory computer-readable medium of claim 31, wherein testing the continuity further includes sensing the electric current, voltage, or heat at the conductive via or the conductive element to which the electric current source, the voltage source, or the heat source was not coupled.

33. The non-transitory computer-readable medium of claim 30, wherein the conductive via comprises a through-silicon via (TSV).

34. The non-transitory computer-readable medium of claim 30, wherein the conductive element comprises a through-silicon via (TSV).

35. A method comprising:
receiving a data file including design information corresponding to a semiconductor device; and
fabricating the semiconductor device according to the design information, wherein the semiconductor device includes:
a conductive via to provide an electrical path through a substrate;
a conductive element; and
a fuse coupled to the conductive via and coupled to the conductive element to provide a conductive path between the conductive via and the conductive element.

36. The method of claim 35, wherein the data file has a GDSII format.

37. The method of claim 35, wherein the data file has a GERBER format.
